(19) United States
(12) Patent Application Publication
(10) Pub. No.: US 2013/0044900 A1
(43) Pub. Date: Feb. 21, 2013

(54) AUDIO PLAYING DEVICE FOR ELECTRONIC DEVICES

(71) Applicants: CHUN-SHENG CHEN, Tu-Cheng (TW); HUA ZOU, Shenzhen City (CN); FENG-LONG HE, Shenzhen City (CN)

(72) Inventors: CHUN-SHENG CHEN, Tu-Cheng (TW); HUA ZOU, Shenzhen City (CN); FENG-LONG HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/479,272

(22) Filed: May 24, 2012

(30) Foreign Application Priority Data
Aug. 15, 2011 (CN) 201110232293.2

(51) Int. Cl. H03G 3/20; H03F 99/00

(52) U.S. Cl. 381/121; 381/120

(57) ABSTRACT

An audio playing device for an electronic device includes an amplifier circuit, a voltage divider circuit, and a speaker. A south bridge of the electronic device is electrically connected to the amplifier circuit via the voltage divider circuit, and a sound card of the electronic device is electrically connected to the amplifier circuit. The south bridge generates electronic signals corresponding to startup prompt tones of the electronic device, and the electronic signals corresponding to startup prompt tones of the electronic device are transmitted to the speaker via the voltage divider circuit and the amplifier circuit to play. The sound card processes audio files, and electronic signals corresponding to the processed audio files are transmitted to the speaker via the amplifier circuit to play.

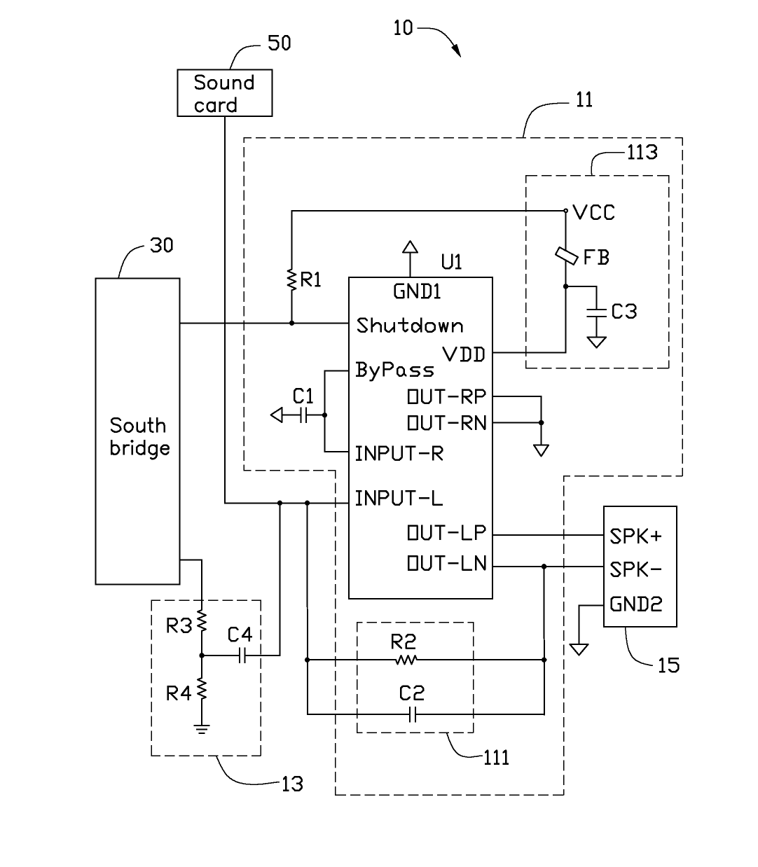

### BACKGROUND

1. Technical Field

The present disclosure relates to audio playing devices, and particularly to an audio playing device for playing startup prompt tones and audio signals of played audio files.

2. Description of Related Art

A personal computer (PC) can include a buzzer and a speaker. The buzzer plays startup prompt tones of the PC during actuation processes of the PC. The speaker plays audio signals corresponding to audio files processed by the PC when the PC is working.

In most PCs, the buzzers use direct current (DC) power supplies, and the speakers use alternating current (AC) power supplies. Therefore, a buzzer and a speaker of a same PC may respectively require different power supply circuits and control circuits. These circuits may complicate a structure of the PC and increase cost of the PC.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

The figure is a circuit diagram of an audio playing device, according to an exemplary embodiment.

### DETAILED DESCRIPTION

The figure is a circuit diagram of an audio playing device 10, according to an exemplary embodiment. The audio playing device 10 can be installed in a personal computer (PC) (not shown) to play startup prompt tones of the PC and audio signals corresponding to audio files processed by the PC. The audio playing device 10 is electrically connected to both a south bridge 30 and a sound card 50 of the PC. In use, the audio playing device 10 plays start prompt tones generated by the south bridge 30 and audio signals corresponding to audio files processed by the sound card 50.

The audio playing device 10 includes an amplifier circuit 11, a voltage divider circuit 13, and a speaker 15, all of which are detailed as follows.

The amplifier circuit 11 includes an amplifier microchip U1, a feedback circuit 111, a power supply circuit 113, a capacitor C1, and a resistor R1. The amplifier microchip U1 can be an ALC105 type microchip, and includes a left channel input pin INPUTL, a right channel input pin INPUTR, a filtering pin Bypass, a power pin VDD, two left channel output pins OUTLP and OUTLN, two right channel output pins OUTRP and OUTRN, a switch pin Shutdown, and ground pin GND 1. The left channel input pin INPUTL is electrically connected to the sound card 50. The right channel input pin INPUTR and the filtering pin Bypass are both connected to ground via the capacitor C1. The power pin VDD and the switch pin Shutdown are both electrically connected to the power supply circuit 113. The amplifier microchip U1 can be turned on and off by electric potentials applied to the switch pin Shutdown. The two left channel output pins OUTLP and OUTLN are both electrically connected to the speaker 15. The two right channel output pins OUTRP and OUTRN, and ground pin GND1 are all connected to ground.

The feedback circuit 111 includes a capacitor C2 and a resistor R2. The capacitor C2 and the resistor R2 are electrically connected in parallel between the left channel output pin OUTLN and the left channel input pin INPUTL.

The power supply circuit 113 includes a power supply VCC, a magnetic bead FB, and a capacitor C3. The power supply VCC is electrically connected to the power pin VDD via the magnetic bead FB. One terminal of the capacitor C3 is electrically connected between the magnetic bead FB and the power pin VDD, and the other terminal of the capacitor C3 is connected to ground. Furthermore, the power supply VCC is electrically connected to the switch pin Shutdown via the resistor R1.

The voltage divider circuit 13 includes a capacitor C4 and two resistors R3, R4. The resistors R3 and R4 are electrically connected in series, and the south bridge 30 is electrically connected to ground via the two resistors R3, R4 connected in series. One end of the capacitor C4 is electrically connected between the resistors R3 and R4, and the other end of the capacitor C4 is electrically connected to the left channel input pin INPUTL.

The speaker 15 includes ground pin GND2, a positive input pin SPK+, and a negative input pin SPK−. Ground pin GND2 is electrically connected to ground. The positive input pin SPK+ and the negative input pin SPK are respectively electrically connected to the two left channel output pins OUTLP and OUTLN.

When the PC is actuated, the power supply VCC outputs a working electric potential to the power pin VDD to supply electric power to the amplifier microchip U1. The magnetic bead FB and the capacitor C3 can filter noise existing in the working electric potential. At the same time, the working electric potential is transmitted to the switch pin Shutdown via the resistor R1, and thus pulls up an electric potential on the switch pin Shutdown to turn on the amplifier microchip U1.

In most PCs, electronic signals corresponding to startup prompt tones generally have electric potentials that are much higher than electric potentials of electronic signals generated by sound cards of the PCs, and thus may be not suitable for being amplified by amplifier circuits configured to amplify the electronic signals generated by the sound cards of the PCs. Therefore, in this embodiment, electric potentials of electronic signals corresponding to startup prompt tones need to be decreased before being input to the amplifier circuit 11 to be amplified. During the actuation process of the PC, the south bridge 30 generates electronic signals corresponding to startup prompt tones, and these electronic signals are input to the left channel input pin INPUTL via the voltage divider circuit 13. In this way, electric potentials of these electronic signals can be regulated to predetermined values by the voltage divider circuit 13. The capacitor C4 can filter noise existing in these electronic signals.

Finally, the regulated electronic signals corresponding to startup prompt tones are amplified by the amplifier microchip U1, and are output to the speaker 15 via the two left channel output pins OUTLP and OUTLN. The speaker 15 transforms the amplified electronic signals into startup prompt tones and plays the startup prompt tones.

When the amplifier microchip U1 is used, the capacitor C1 can filter noise generated in the amplifier microchip U1. The feedback circuit 111 can transmit electronic signals output from the left channel output pin OUTLN to the left channel input pin INPUTL to form negative feedback, thereby stabilizing the amplified electronic signals output by the amplifier microchip U1. Furthermore, when the actuation process of the PC is completed, the south bridge 30 can stop the startup prompt tones by pulling down the electric potential on the switch pin Shutdown and turning off the amplifier microchip U1.

When the PC is working, the sound card 50 processes audio files and generates electronic signals corresponding to the audio files. In most PCs, electronic signals generated by sound cards of the PCs are suitable for being directly amplified by amplifier circuits of the PCs. Therefore, the electronic signals generated by the sound card 50 are directly input to the left channel input pin INPUTL of the amplifier circuit 11. The amplifier microchip U1 amplifies these electronic signals and output the amplified electronic signals to the speaker 15 via the two left channel output pins OUTLP and OUTLN. The speaker 15 transforms the amplified electronic signals into audio signals corresponding to the processed audio files and plays the audio signals. The capacitor C1 and the feedback circuit 111 can also be used according to above methods.

The audio playing device 10 can play both startup prompt tones of the PC and audio signals corresponding to audio files processed by the PC using the speaker 15. Compared with common PCs, the PC with the audio playing device 10 does not need any buzzer, and thus power supply circuits and control circuit corresponding to the buzzer can be omitted in the PC. In this way, a structure of the PC is simplified, and cost of the PC is decreased.

It is readily appreciated that the audio playing device 10 can also be used in other electronic devices with south bridges and sound cards, such as single-microchip computers and personal digital assistants (PDAs), according to the aforementioned methods.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. An audio playing device for an electronic device that includes a south bridge and a sound card, the audio playing device comprising:
an amplifier circuit;
a voltage divider circuit electrically connected to the amplifier circuit; and
a speaker electrically connected to the amplifier circuit;
wherein the south bridge is electrically connected to the amplifier circuit via the voltage divider circuit, the south bridge generates electronic signals corresponding to startup prompt tones of the electronic device, and the electronic signals corresponding to startup prompt tones of the electronic device are transmitted to the speaker via the voltage divider circuit and the amplifier circuit to play; and
wherein the sound card is electrically connected to the amplifier circuit, and in response to the sound card processing audio files, electronic signals corresponding to the processed audio files are transmitted to the speaker via the amplifier circuit to play.

2. The audio playing device as claimed in claim 1, wherein the amplifier circuit includes an amplifier microchip, and the amplifier microchip includes a left channel input pin and two left channel output pins, the south bridge is electrically connected to the left channel input pin via the voltage divider circuit to input the electronic signals corresponding to startup prompt tones to the amplifier unit, the sound card is electrically connected to the left channel input pin to input the electronic signals corresponding to the played audio files to the amplifier unit, and the speaker is electrically connected to the two left channel output pins to receive electronic signals amplified by the amplifier microchip.

3. The audio playing device as claimed in claim 2, wherein the speaker includes a positive input pin and a negative input pin, and the positive input pin and the negative input pin are respectively electrically connected to the two left channel output pins.

4. The audio playing device as claimed in claim 3, wherein the amplifier circuit further includes a feedback circuit, and the left channel output pin that is electrically connected to the negative input pin is electrically connected to the left channel input pin via the feedback circuit.

5. The audio playing device as claimed in claim 2, wherein the amplifier circuit further includes a power supply circuit electrically connected to the amplifier microchip and supplying electric power to the amplifier microchip.

6. The audio playing device as claimed in claim 5, wherein the amplifier microchip further includes a power pin configured to input electric power, and the power supply circuit includes a power supply, a magnetic bead, and a capacitor; the power supply is electrically connected to the power pin via the magnetic bead, one terminal of the capacitor is electrically connected between the magnetic bead and the power pin, and the other terminal of the capacitor is connected to ground.

7. The audio playing device as claimed in claim 6, wherein the amplifier microchip further includes a switch pin, and the amplifier microchip is capable of being turned on and off by electric potentials applied on the switch pin.

8. The audio playing device as claimed in claim 7, wherein the amplifier circuit further includes a resistor, and the power supply is electrically connected to the switch pin via the resistor.

9. The audio playing device as claimed in claim 6, wherein the south bridge is electrically connected to the switch pin.

10. The audio playing device as claimed in claim 2, wherein the amplifier circuit further includes a capacitor, the amplifier microchip further includes a right channel input pin and a filtering pin, and both the right channel input pin and the filtering pin are electrically connected to ground via the capacitor.

11. The audio playing device as claimed in claim 2, wherein the amplifier microchip further includes two right channel output pins, and both the two right channel output pins are grounded.
